(19) United States
(12) Patent Application Publication
(10) Pub. No.: US 2025/0355432 A1
(43) Pub. Date: Nov. 20, 2025

(54) METHOD FOR GENERATING A VIRTUAL RAY TRACING SENSOR SIGNAL

(71) Applicant: dSPACE GmbH, Paderborn (DE)

(72) Inventor: Matthias GOETTE, Paderborn (DE)

(73) Assignee: dSPACE GmbH, Paderborn (DE)

(21) Appl. No.: 19/211,954

(22) Filed: May 19, 2025

(30) Foreign Application Priority Data
May 17, 2024 (EP) 24176629.4

(51) Int. Cl. G05B 23/02; G06F 30/20; G06T 15/06

(52) U.S. Cl. CPC G05B 23/0256; G06F 30/20; G06T 15/06

(57) ABSTRACT

A computer-implemented method and system for generating a virtual ray tracing sensor signal of a vehicle sensor that is to be virtually tested for testing a virtually simulated or autonomous driving function of an ego vehicle.

This nonprovisional application claims priority under 35 U.S.C. § 119 (a) to European Patent Application No. 24176629.4, which was filed on May 17, 2024, and which is herein incorporated by reference.

### BACKGROUND OF THE INVENTION

### Field of the Invention

The invention relates to a computer-implemented method for generating a virtual ray tracing sensor signal of a vehicle sensor that is to be virtually tested for testing a virtually simulated, in particular autonomous, driving function of an ego vehicle.

The invention further relates to a system for generating a virtual ray tracing sensor signal of a vehicle sensor that is to be virtually tested for testing a virtually simulated, in particular autonomous, driving function of an ego vehicle.

The invention further relates to a computer program product that includes a computer program, and to a computer-readable data medium that includes program code of a computer program.

### Description of the Background Art

In the constantly evolving world of automotive technology, the role of simulation is becoming increasingly important, in particular in the development and testing of autonomous driving functions.

An element in this context is the use of virtual sensors that simulate the actual surroundings of a vehicle in virtual space. Among these virtual sensors, the ray tracing sensor represents a key technology.

Ray tracing, a technique that originated from the field of computer graphics, is now also finding application in the simulation of vehicle sensors, due to its ability to realistically simulate light and its interaction with various surfaces.

Methods for generating a virtual ray tracing sensor signal that is used for checking and validating the functions of an autonomous vehicle, the so-called “ego vehicle,” in a virtually simulated environment are basically known.

Due to the realistic simulation of the sensor-based detection of the surroundings, this approach allows detailed and comprehensive evaluation of the performance and reliability of autonomous driving systems without the need for physical tests under potentially hazardous conditions.

However, the known methods and systems have the disadvantage that a large amount of computing time and computing resources are often needed. Thus, in this context there is further potential for development.

### SUMMARY OF THE INVENTION

It is therefore an object of the invention to provide an improved method and/or system for generating a virtual ray tracing sensor signal.

The object is achieved by a computer-implemented method for generating a virtual ray tracing sensor signal of a vehicle sensor that is to be virtually tested for testing a virtually simulated, in particular autonomous, driving function of an ego vehicle, and by a method.

The object is further achieved by a system for generating a virtual ray tracing sensor signal of a vehicle sensor that is to be virtually tested for testing a virtually simulated, in particular autonomous, driving function of an ego vehicle.

The object is further achieved by a computer program product that includes a computer program, and by a computer-readable data medium that includes program code of a computer program.

The invention relates to a computer-implemented method for generating a virtual ray tracing sensor signal of a vehicle sensor that is to be virtually tested for testing a virtually simulated, in particular autonomous, driving function of an ego vehicle.

In general the term “ego vehicle” can represent a virtual vehicle in the center of a simulation or a test. E.g. the vehicle for that a new function is to be developed or tested. Typically, one skilled in the art uses such to distinguish a central vehicle (“ego”) from other vehicles or traffic participants (pedestrians, bicycles, etc.) that are usually called “fellows” or “fellow vehicles” that appear in a simulation or test and can interact or have an impact on the ego. For example, there may be several vehicles in a scenario in order to test a function of the ego vehicle but these fellow vehicles may not have the function to be tested, e.g. automatic braking systems.

In an example, the method comprises: providing scene information in a first, in particular 64 bit-based, data format, the scene information containing information concerning the ego vehicle and at least one object in space; providing the scene information in a second, in particular 64 bit-based, data format that is converted based on the first data format; providing the scene information in a third, in particular 32 bit-based, data format that is converted based on the second data format and used for virtual ray tracing of at least one object in space; in the third data format, subdividing the space according to a search grid and determining which of the at least one object interacts with an approximated ray of the vehicle sensor to be virtually tested; in the third data format, virtual ray tracing of the determined at least one object; and generating the virtual ray tracing sensor signal based on the traced at least one object for testing the virtually simulated, in particular autonomous, driving function of the ego vehicle.

In an example, the method may also comprises: providing scene information in a first, in particular 64 bit-based, data format, the scene information containing information concerning the ego vehicle and at least one object in space; providing the scene information in a third, in particular 32 bit-based, data format that is converted based on the first data format and used for virtual ray tracing of at least one object in space; in the third data format, subdividing the space according to a search grid and determining which of the at least one object interacts with an approximated ray of the vehicle sensor to be virtually tested; in the third data format, virtual ray tracing of the determined at least one object; and generating the virtual ray tracing sensor signal based on the traced at least one object for testing the virtually simulated, in particular autonomous, driving function of the ego vehicle.

According to the example of the method, the scene information in the third data format may also be obtained directly from scene information of the first data format, in particular without a conversion into the second data format taking place. Although the conversion from the first data format into the second data format and from the second data format into the third data format is preferred, a direct conversion from the first data format into the third data format can also take place. The examples correspondingly apply for both methods without having to be redundantly mentioned.

The steps according to the invention as well as further optional steps do not necessarily have to be carried out in the indicated order, and instead may also be carried out in some other order. In addition, further intermediate steps may be provided. The individual steps may also include one or more substeps without thus departing from the scope of the method according to the invention.

The invention further relates to a system for generating a virtual ray tracing sensor signal of a vehicle sensor that is to be virtually tested for testing a virtually simulated, in particular autonomous, driving function of an ego vehicle, the system including an evaluation and computing device.

The system can be designed to carry out the following steps: providing (S1A) scene information in a first, in particular 64 bit-based, data format, the scene information containing information concerning the ego vehicle and at least one object in space; providing (S1B) the scene information in a second, in particular 64 bit-based, data format that is converted based on the first data format; providing (S1C) the scene information in a third, in particular 32 bit-based, data format that is converted based on the second data format and used for virtual ray tracing of at least one object in space; in the third data format, subdividing (S2) the space according to a search grid and determining (S3) which of the at least one object interacts with an approximated ray of the vehicle sensor to be virtually tested; in the third data format, virtual ray tracing (S5) of the determined at least one object; and generating (S6) the virtual ray tracing sensor signal based on the traced at least one object for testing the virtually simulated, in particular autonomous, driving function of the ego vehicle.

The statements made for the method correspondingly apply for the device. It should be understood that linguistic variations of features formulated according to the invention may be reworded for the device according to standard usage, without such formulations having to be explicitly mentioned here.

In conventional methods and systems for generating a virtual ray tracing sensor signal of a vehicle sensor that is to be virtually tested, in particular a ray tracing sensor such as lidar, radar, or ultrasound, in addition to problems related to computing power, problems with the accuracy of the sensor simulation continually arise. Thus far, for such ray tracing sensors an image scene has been parsed, in particular per frame, in the second data format (Unreal Engine 5) into the third data format (an Nvidia Optix scene).

The information in the third data format is usually present as a type of tree structure. Thus far, a static, i.e., nonmoving, portion of the particular scene has been converted into a stationary data structure in which, for example, the vertices (of each triangle) in the scene are described by absolute world coordinates. In the context of the present invention, the origin of the world coordinate system lies at an arbitrary point within the scene. However, this generally results in problems with the accuracy of the sensor simulation, since the third data format (Nvidia Optix) operates with 32-bit floating-point numbers according to the IEEE 754-2008 standard. This results in data losses concerning important details of the scene.

For example, in the simulation of the ray tracing a round surface of an object no longer appears smooth, and instead has a stepped appearance when the distance from the coordinate origin is great. In addition, for larger scenes the memory usage as well as the computing time increase nonlinearly. This results in decreased tracing performance.

It has been possible to solve the above-described problems by use of the present method and system.

In the third data format, the space is subdivided according to a search grid, and it is determined which of the at least one object interacts with an approximated ray of the vehicle sensor to be virtually tested. In other words, the static or nonmoving objects depicted in the scenes, i.e., the static surroundings, are divided into sections (chunks). During the simulation of the ray tracing, this allows a check for which portions or sections of the static world are relevant for the simulated vehicle sensor. Thus, only these sections can be taken into account.

Thus, only objects that are in the range of a vehicle sensor to be simulated are part of a final evaluation structure. The assignment to sections having a fixed acceleration structure, compared to taking single objects into account individually, has the advantage that the number of relevance tests and the number of individual subdata structures in the third data format (Optix scene) are reduced, and in particular are independent of a local accumulation of objects. This increases the performance of the underlying ray tracing algorithm. By use of the present method, a high level of simulation accuracy and a high simulation speed may be achieved in the simulation of ray tracing sensors, in particular regardless of the size of the simulated scene.

In the present case, the sectioning of the scene into sections or smaller scenes or scene excerpts allows improved ray tracing performance, since unneeded parts of the scene may, for example, be moved from the graphics card memory to the host memory. Thus, for example, even more vehicle sensors may be simultaneously simulated and computed for each graphics card. Alternatively or additionally, it is also possible to simulate and compute significantly larger starting scenes. The computing power problems that have formerly occurred are thus solved, and no longer have to be accepted as a limitation.

The first data format can be a ModelDesk data format. The second data format can be an Unreal Engine 5 data format. The third data format can be an Nvidia Optix data format.

ModelDesk is a software environment that is often used in conjunction with dSpace systems. The ModelDesk data format refers to the manner in which data and projects are stored and organized within the ModelDesk software. This software is used for the parameterization, management, and optimization of models in real-time simulations, in particular in the automotive industry for the development of driver assistance systems and other vehicle control systems

Unreal Engine 5 (UE5) is a powerful, widely used game engine developed by Epic Games. The data format in UE5 refers to the manner in which assets, scenes, materials, textures, and other elements within the engine are stored and handled. UE5 uses numerous file formats, among them proprietary formats such as .uasset for assets. These formats are optimized in order to support the powerful functions of the engine, for example photorealistic ray tracing, dynamic illumination, and highly developed material systems.

OptiX is an application framework from Nvidia for GPU-accelerated ray tracing. The “data format” in OptiX presumably refers to the manner in which scenes, geometries, materials, and shaders are defined and organized within the framework to allow ray tracing computations. OptiX operates with numerous data formats, and offers interfaces for integration into existing rendering pipelines, with CUDA being used as the basis for describing ray tracing operations.

The determination of which of the at least one object interacts with an approximated ray of the vehicle sensor to be virtually tested particularly preferably takes place in each or for each (new) frame.

Virtual ray tracing of an object in space refers to a computer-assisted technique that is used to simulate the path of rays through a virtual environment, for example to generate the visual effects that result when light strikes objects. This method is used in particular in computer graphics, and also in the development of visualization, optical, or technical lighting systems. However, it also finds application in the simulation of sensor systems for vehicles.

The process of virtual ray tracing may begin with the starting points of the rays. From here, rays are tracked through the virtual scene. The selection of the starting points or the direction of the rays is based on the computation time, not on the physics. Thus, for example, in computer graphics it is common to track rays backwards starting from a so-called “eye,” whereas computations in illumination technology generally proceed from a light source. When a ray strikes an object, the interactions with the surface of the object are computed, including reflection, refraction, and absorption, in particular based on the material properties of the object.

By application of the ray tracing method to objects in a virtual space, it is possible to precisely simulate the physical properties of light and materials. In the application to vehicle sensors, this technique can be used to simulate the interaction of active sensors with the vehicle surroundings. These sensors, for example lidar, radar, or ultrasound, emit a (sensor) signal for the measurement, which interacts with objects and surfaces in the surroundings in such a way that that at least a portion of the signal returns to the sensor. By means of the simulation, developers can precisely test and validate the performance of sensor systems under various conditions and scenarios without relying on physical prototypes or tests.

An approximated ray in ray tracing is thus part of a simplified representation of physical waves, in particular electromagnetic or acoustic waves, via one or more rays in the mathematical-geometric sense, which is used to improve the computation efficiency, in particular in situations in which a perfectly precise simulation of wave phenomena is not absolutely necessary. The approximation may be even further simplified, for example by reducing the precision in the computation of the ray propagation, or by assuming simplified interaction models for the striking of the ray on objects. The objective is to decrease the number of required computations by reducing the level of detail or accuracy in areas that are less critical for the final result.

A search grid, which can also be referred to as a spatial subdivision grid or spatial hashing grid, is a method for organizing and optimizing the ray tracing computations in a three-dimensional scene. The space is subdivided into a grid made up of fairly small, discrete cell sections. Each object in the scene is assigned to one or more of these cells, based on its position and extension. When a ray is tracked through the scene, the ray tracing system no longer has to examine the entire scene for potential collisions with objects. Instead, the ray tracing system checks only the objects in the cells through which the ray travels.

This method improves the efficiency of ray tracing, in particular in complex scenes with many objects, since it reduces the number of necessary computations of collisions between rays and objects. Due to reducing the quantity of checks that are necessary for each ray, the overall computation time for ray tracing of a scene may be drastically decreased, which is particularly important for real-time applications such as interactive graphics or the simulation of sensor signals in real time.

In a further aspect, it is proposed that the method also comprises: transforming (S4A) coordinates of the determined at least one object from the world coordinate system into a coordinate system of the vehicle sensor to be virtually tested, based on location information of the determined at least one object and/or of the vehicle sensor, which is obtained from the second data format, and based on ray information concerning the approximated ray; or transforming (S4B) coordinates of the vehicle sensor from the world coordinate system into a coordinate system of the determined at least one object, based on location information of the determined at least one object and/or of the vehicle sensor, which is obtained from the second data format, and based on ray information concerning the approximated ray.

The transformation may take place using any given coordinate transformation algorithm. This transformation is preferably selected in such a way that either the vehicle sensor or the object is situated at or in the vicinity of the origin of the coordinate system. As a result of either, the inputs of the position vectors regarding the object or the vehicle sensor become smaller.

Due to subdividing a large static starting scene into small sections, it is possible to transform only necessary subareas of the scene (for example, the sections surrounding the vehicle sensor), as described, into the sensor coordinate system or object coordinate system. Due to the coordinate transformation, all absolute (reference) coordinates are small and the accuracy problem is solved. The transformation matrices are preferably determined from the position vectors, which are known from the second data format with 64-bit float accuracy and which thus provide high accuracy all the way to much larger coordinates.

The location information of the determined at least one object and/or of the vehicle sensor, which is obtained from the second data format, can contain information concerning coefficients of a transformation matrix.

Based on the second data format, it is also particularly preferably possible to determine or provide an item of location information and/or an item of bounding box information concerning the at least one object.

Bounding box information describes the spatial boundaries of an object within a defined space. A bounding box is generally a simple geometric volume or a shape, such as a rectangle (in 2D) or a cube (in 3D) that completely encompasses the object.

The location information may also contain absolute and/or relative location information concerning the at least one object.

A transformation matrix is a mathematical tool that is used in many fields such as computer graphics, robotics, physics, and more in order to perform various types of transformations such as translation (displacement), rotation, scaling, and shearing of objects in a multidimensional space. The coefficients within a transformation matrix represent the specific properties and the extent of the transformation that is applied to an object or a point.

The coefficients of a transformation matrix define how a point and/or object in space is transformed. When the matrix is multiplied by a vector that represents the position of a point, a new vector is obtained which indicates the position of the point after application of the transformation. Transformation matrices may also be multiplied by one another in order to represent complex transformations by a single matrix.

The scene information also can contain movement information of the ego vehicle and/or location and/or movement information concerning the at least one object.

The movement information may contain information concerning an in particular directionally dependent speed and/or in particular directionally dependent acceleration. In addition, the movement information may also contain information concerning a future change in speed and/or acceleration, for example as a type of vector flow information between scenes and/or scene excerpts.

The virtual ray tracing sensor signal can include information concerning a distance and/or a speed of the at least one object relative to the ego vehicle.

The information concerning a distance and/or a speed may also contain information concerning a change in a distance and/or a speed.

In a further aspect, it is proposed that the first data format includes in particular abstract modeling of the at least one object in space, a reference, and/or a pointer to a detailed description of the at least one object in the second data format, the first data format having, for example, a ModelDesk data format.

The first data format offers abstract modeling of the object, while the second data format provides a detailed description. The first data format includes a simplified or abstracted representation of the object. This abstraction may be in the form of a bounding box, a placeholder, or some other simplified geometry that represents the object in space, without going into fine detail. The use of abstract modeling in the first data format increases the processing speed, in particular in processes where complete attention to detail is not necessary, for example in preliminary collision checks or in rapid spatial analysis. In contrast to the first format, the second data format contains a comprehensive and detailed description of the object. This may include texture information, exact geometries, materials, physical properties, and more. The second format is preferably used as a supplement to the first format, in that it provides the information necessary for detailed analyses, renderings, or simulations. The second format is typically referenced when the abstract representation is not sufficient for a specific application.

The first data format also can include data and/or information from a driving dynamics simulation of the ego vehicle.

In principle, any given information concerning the driving dynamics simulation of the ego vehicle may be included. In a driving dynamics simulation of an ego vehicle, various aspects of the vehicle and its interaction with the surroundings are modeled in order to analyze the behavior and the performance of the vehicle under various conditions and scenarios. Mentioned as examples are the total mass of the vehicle as well as the distribution of weight on the front and rear axles. In addition, the moments of inertia of the vehicle about the three main axes, which influence the response of the vehicle to rotational movements, may be simulated. Furthermore, the air resistance coefficient (Cw value) and the cross-sectional area of the vehicle, which determine the air resistance, as well as aerodynamic output forces may be simulated. In addition, the motor characteristic, for example a power curve, maximum torque, and torque curve of the motor over the entire rotational speed range, may be simulated. Moreover, the transmission and/or drive type (front, rear, all-wheel) may be simulated. The chassis dynamics, for example suspension, steering, wheels, and tires, may be simulated.

The second data format can include the detailed description of the at least one object as information concerning a condition and/or a surface and/or a surface property and/or an object class and/or an object type, the second data format preferably having an Unreal Engine data format.

In this way, absorption properties and/or reflection and scattering properties of the least one object can be described by physical parameters, which are then used in the ray tracing algorithm for the computation.

In a further aspect, it is proposed that the third data format includes information concerning vertices into which a surface of the at least one object is subdivided, the information concerning the vertices being used to generate the virtual ray tracing sensor signal as a function of the at least one approximated ray, the third data format having an Nvidia Optix data format.

Vertices (singular: vertex) are elements in geometry and computer graphics which represent points in space. In three-dimensional modeling and graphics, vertices are the corner points of polygons, typically triangles or quadrilaterals, that make up the surfaces of 3D models. Each vertex generally has multiple attributes which define its properties and role within a mesh (a network made up of polygons). The most important aspect of a vertex is its position in space, customarily indicated by coordinates in a three-dimensional coordinate system (x, y, z). Normals are vectors that are perpendicular to the surface of a polygon, and are important for illumination computations because they determine how light is reflected from the surface. Texture coordinates (also referred to as UV coordinates) define how a two-dimensional texture is mapped onto the surface of a 3D model. They specify which part of the texture is applied to a certain vertex. Specific colors may also be assigned to some vertices, and then together with illumination models and/or texture information contribute to the final color of the pixel in which the vertex is rendered.

In computer graphics, the vertices of a model are manipulated by transformation matrices in order to scale, rotate, and shift models. This is a key process in the representation of 3D models on the screen, in which the vertices are sent through various transformation steps (model, view, and projection transformations) before the final image position of each vertex is computed and the model is rendered on the screen. Vertices thus form the basic building blocks for representing and manipulating 3D models and scenes in computer graphics.

It should be noted that the information concerning vertices not only refers to the geometry of the at least one object, but may also contain information concerning scattering properties of the at least one object. In the present context, the term “scattering” is understood to mean any interaction of the ray with the surface of the at least one object.

In a further aspect, it is proposed that the movement information of the ego vehicle contains information concerning a predetermined movement, in particular by iterative adjustment to the generated ray tracing sensor signal, or by a driving algorithm for movement information that is intended for an autonomous driving function.

A predetermined route or change of route of the ego vehicle may be specified. In addition, a driving behavior of the ego vehicle may be described in the form of a travel algorithm. It is thus possible to also map or describe a complex driving behavior of the ego vehicle.

In a further aspect, it is proposed that the method is used in a software-in-a-loop and/or a hardware-in-a-loop test scenario for testing of the vehicle sensor to be virtually tested.

For software-in-the-loop (SiL), the software to be tested is executed in a simulated environment that generally runs on a standard PC or server. No actual control units or hardware components are used, and instead all relevant systems and environments are simulated entirely in software. SiL is used to check the behavior of the software under various operating conditions without dealing with the hardware integration. It allows early detection and elimination of software errors as well as checking of the software logic and functionality.

Hardware-in-the-loop (HiL) tests integrate physical hardware, for example a control unit, into an otherwise simulated environment. The control units are connected to a simulated environment that is generated using specialized Hil simulation hardware and software. Sensors and actuators are replaced by the simulation, while the control unit “thinks” that it is connected in a real system. Hil is used to test the interaction between the hardware and the software under realistic operating conditions, without incurring risks for persons or materials. It allows testing of the response of control units to various input signals, and checking of real-time capabilities.

In a further aspect, it is proposed that the vehicle sensor includes a lidar sensor or a radar sensor or an ultrasound sensor or an infrared sensor.

Other types of sensors are also conceivable, so that the above listing is not to be construed as exhaustive.

In a further aspect, a computer program including program code is claimed in order to carry out at least parts of the present method in one of its aspects when the computer program is executed on a computer. In other words, a computer program (product) is used that includes commands which, when the program is executed by a computer, prompt the computer to carry out the method/the steps of the method in one of its aspects.

In a further aspect, a computer-readable data medium including program code of a computer program is proposed in order to carry out at least parts of the present method in one of its aspects when the computer program is executed on a computer. In other words, the invention relates to a computer-readable (memory) medium that includes commands which, when executed by a computer, prompt the computer to carry out the method/the steps of the method in one of its aspects.

The described examples may be combined with one another.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a schematic flow chart of an example of the method;

FIG. 2 shows an example illustration of the method;

FIG. 3 shows an example illustration of the method;

FIG. 4 shows an example illustration of the method;

FIG. 5 shows an example illustration of the method;

FIG. 6 shows an example illustration of the method; and

FIG. 7 shows schematic sectioning of a space in which multiple objects are present.

### DETAILED DESCRIPTION

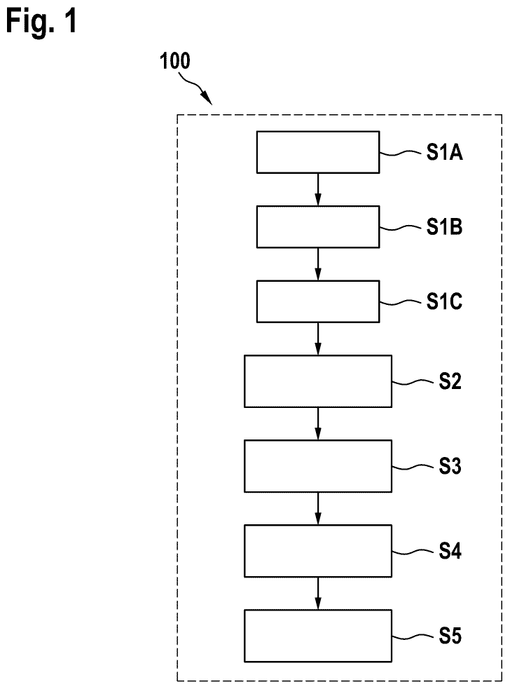

FIG. 1 shows a schematic flow chart of a computer-implemented method for generating a virtual ray tracing sensor signal of a vehicle sensor that is to be virtually tested for testing a virtually simulated, in particular autonomous, driving function of an ego vehicle.

The method is preferably used in a software-in-a-loop and/or a hardware-in-a-loop test scenario for testing of the vehicle sensor to be virtually tested.

In any example, the computer-implemented method may be carried out, at least in part, by a system 100, which for this purpose may include multiple components, for example one or more provision devices and/or at least one evaluation and computing device. It is understood that the provision device may have a design in combination with the evaluation and computing device, or may be different from same. In addition, the system 100, which may also be part of a further system, may include a memory device and/or an output device and/or a display device and/or an input device.

The computer-implemented method can comprise at least the following steps:

Provision of scene information in a first, in particular 64 bit-based, data format takes place in a step S1A, the scene information containing information concerning the ego vehicle and at least one object in space.

Provision of the scene information in a second, in particular 64 bit-based, data format takes place in a step S1B, the second data format being converted based on the first data format. The second data format is preferably an Unreal Engine 5 data format. The scene information includes, for example, movement information of the ego vehicle and/or location and/or movement information concerning the at least one object.

Provision of the scene information in a third, in particular 32 bit-based, data format takes place in a step S1C, the third data format being converted based on the second data format, and at least one object in space is used for the virtual ray tracing. The third data format is preferably an Optix data format.

In the third data format, subdivision of the space according to a search grid takes place in a step S2, and determination of which of the at least one object interacts with an approximated ray of the vehicle sensor to be virtually tested takes place in a step S3.

In the third data format, virtual ray tracing of the determined at least one object takes place in a step S4.

Generation of the virtual ray tracing sensor signal takes place in a step S5, based on the traced at least one object for testing the virtually simulated, in particular autonomous, driving function of the ego vehicle. The virtual ray tracing sensor signal includes information concerning a distance and/or a speed of the at least one object relative to the ego vehicle.

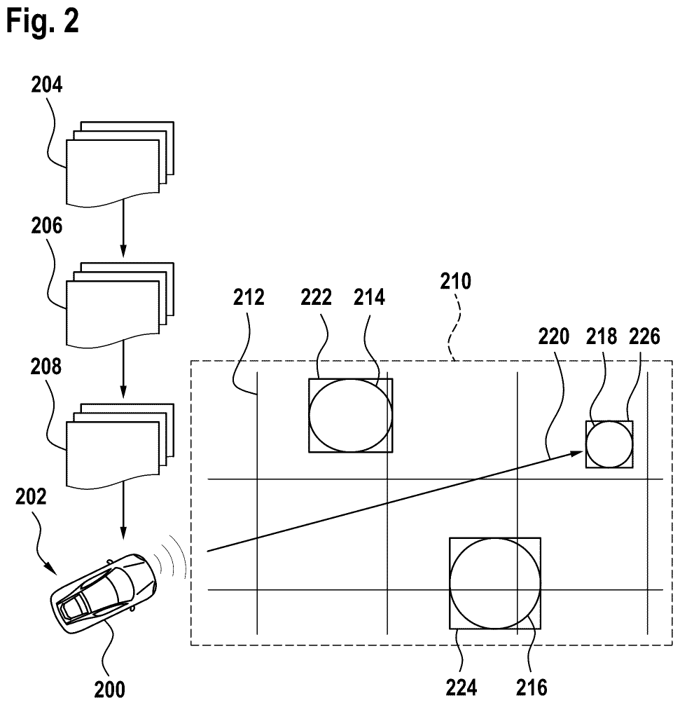

FIGS. 2 through 6 show example illustrations of how the method is used for simulation of a vehicle sensor. Ultimately, a virtual ray tracing sensor signal of a vehicle sensor 200 that is to be virtually tested for testing a virtually simulated, in particular autonomous, driving function of an ego vehicle 202 is generated. However, this is preceded by several data processing steps in order to make the simulation more accurate. The vehicle sensor 200 may include a lidar sensor or a radar senor or an ultrasound sensor or an infrared sensor.

FIG. 2 shows an example scene that is present in the first data format (a ModelDesk data format), for example. As described above, the scene has been converted from a first data format 204 (ModelDesk data format) into a second data format 206 (Unreal Engine data format), and lastly into a third data format 208 (Nvidia Optix data format).

In the third data format, subdivision of the scene or a space 210 according to a search grid 212 takes place, and a determination of which of the at least one object 214, 216, 218 interacts with an approximated ray 220 of the vehicle sensor 200 to be virtually tested takes place. As is apparent from FIG. 2, the ray 220 interacts only with the object 218 within the search grid 212. In contrast, the objects 214 and 216 do not interact with the ray 220 and are thus masked from further consideration. A bounding box 222, 224, 226 is delineated for each of the objects 214, 216, 218, respectively. The bounding box information concerning the objects 214, 216, 218 is preferably provided in the second data format 206.

The first data format 204 includes in particular abstract modeling of the at least one object 214, 216, 218 in the space 210, a reference, and/or pointer to a detailed description of the at least one object 214, 216, 218 in the second data format 206. The first data format 204 may also include data and/or information from a driving dynamics simulation of the ego vehicle 202.

The second data format 206 may include the detailed description of the at least one object 214, 216, 218 as information concerning a condition and/or a surface and/or a surface property and/or an object class and/or an object type. The second data format 206 may preferably have an Unreal Engine data format.

The third data format 208 may include information concerning vertices into which a surface of the at least one object 214, 216, 218 is subdivided, the information concerning the vertices being used to generate the virtual ray tracing sensor signal as a function of the at least one approximated ray 220. The third data format 208 may have an Nvidia Optix data format.

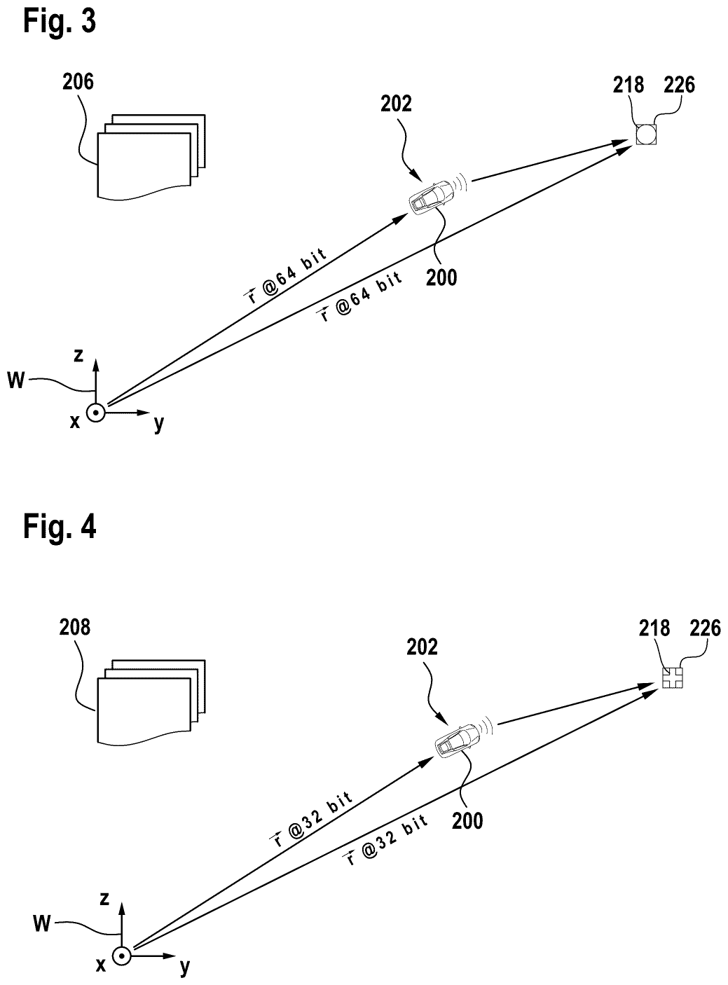

Of the objects 214, 216, 218 that are present in the space 210, only the object 218 is illustrated in FIGS. 3 through 6, since the other objects 214, 216 are ignored for the further evaluation or analysis by subdividing the space 210 and determining the interaction with the ray 220. The object 218 is illustrated with its bounding box 226. The object 218 according to FIG. 3 is illustrated in the second data format, Unreal Engine 5. The second data format 206 is a 64-bit data format, so that the information is present in a 64-bit format.

FIG. 4 illustrates the object 218 and the bounding box 226 in the third data format 208, which is a 32-bit data format. Due to the 32-bit representation and the simulated distance of the object 218 or the vehicle sensor 200 from a global coordinate origin, the actually round surface of the object 218 appears stepped, as schematically depicted in FIG. 4. When generating a ray tracing sensor signal in the simulation environment Nvidia Optix, this would result in a loss of accuracy, which, however, may be avoided using an example of the present invention.

Namely, in the present case a transformation of coordinates of the determined at least one object 218 from the world coordinate system W into a coordinate system F of the vehicle sensor 200 to be virtually tested may take place based on location information, for example via the bounding box 226, of the determined at least one object 218 and/or of the vehicle sensor 200, which is obtained from the second data format 206.

Alternatively, it is also conceivable for the transformation of coordinates of the vehicle sensor 200 from the world coordinate system W into a coordinate system of the determined at least one object 218 to take place based on location information of the determined at least one object 218 and/or of the vehicle sensor 200, which is obtained from the second data format 206, and also based on ray information of the approximated ray.

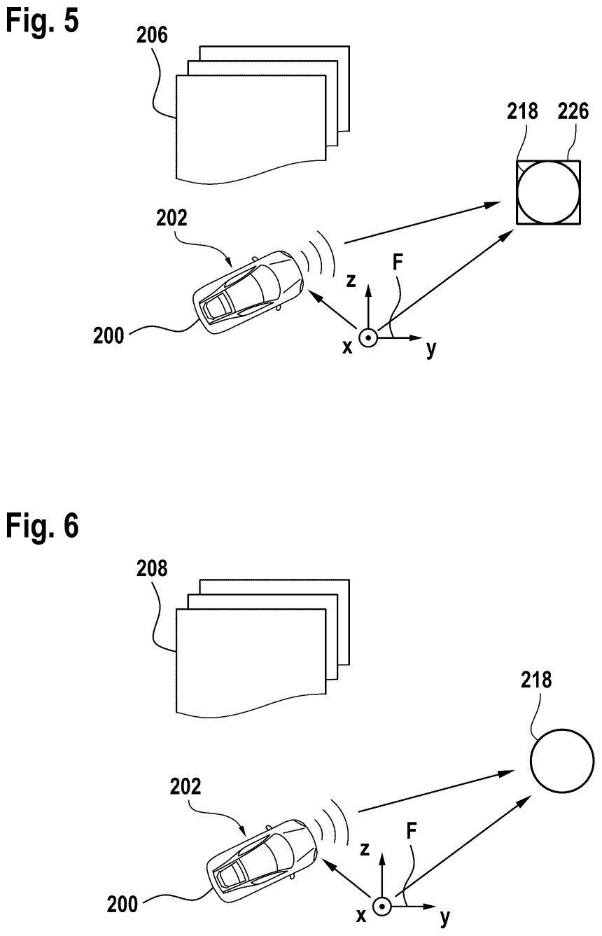

The result of the transformation from the coordinate system W into the coordinate system F is illustrated in FIG. 5. The object 218 and the vehicle sensor 200 are now closer to the coordinate origin, so that the inputs and the reference information become “smaller.” In both cases, due to the coordinate transformation the (global) coordinate system W is brought “closer” to the vehicle sensor 200 or the object 218, as also shown in FIG. 5.

The result of the transformation according to FIG. 5 is schematically illustrated in the second data format (Unreal Engine 5).

Due to the transformation, the object properties of the surface of the object 218 may now be represented as “round” and no longer as stepped in the third data format 208 as well, which is present in 32-bit resolution, as depicted in FIG. 6. The accuracy in generating the virtual ray tracing sensor signal may be increased in this way.

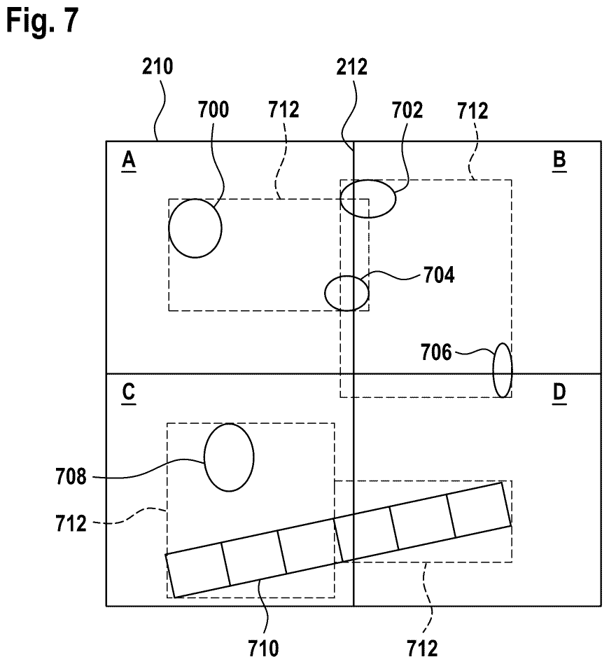

FIG. 7 shows a division or subdivision of the space 210 into four sections A, B, C, D by the search grid 212. This may take place using an appropriate algorithm that “meaningfully” divides the static world or the space 210 into the sections A, B, C, D. The “optimal” size of a section A, B, C, D is preferably related to a maximum visual range of the vehicle sensor 200, and may preferably be correspondingly configured. The final size of a section A, B, C, D preferably results from a respective enveloping bounding box of all objects 700, 702, 704, 706, 708, 710 present in the space 210, which preferably have their respective object midpoint in the particular section A, B, C, D. A section A, B, C, D may thus possibly also become larger than originally defined. In addition, size differences between sections A, B, C, D are conceivable. Thus, strictly as an example, sections A and B may be larger or smaller than sections C and D.

Since multiple instances of the same object may exist in the space 210, depending on the object size, the instances in the third data format (Optix) being describable in particular by an individual data structure with various object-to-world transformations, the approach of object assignment which encompasses all sections, illustrated in FIG. 7, is better suited than the grids or meshes of the objects 700, 702, 704, 706, 708, 710 for making divisions at the section boundaries.

The grids or meshes of larger objects, for example object 710, which may describe objects such as streets or buildings, for example, are therefore preferably uniformly subdivided into smaller subsections 712 which have only a fraction of the size of the particular sections A, B, C, D. As a result, the individual sections A, B, C, D each overlap with neighboring sections by at most one-half of this subdivision size. Due to the section-independent subdivision, the individual submeshes may be further instantiated. The sections A, B, C, D are preferably defined in three dimensions, so that, for example, the upper portions of high-rise buildings may be ignored when they are not in the visual range of the vehicle sensor 200 at ground level. This procedure results in reduced memory and increased performance. To further reduce the number of necessary checks when generating the ray tracing sensor signal, the bounding boxes of multiple neighboring sections A, B, C, D are preferably also recombined. It is preferably checked whether the higher-order bounding box is in the range of the vehicle sensor 200. The lower-order subsections 712 are checked only when this is the case. Continuing this sectioning or subdividing of the space 210 thus preferably results in a section tree structure. The number of checks per section that are necessary for generating the ray tracing sensor signal, and optionally also of this multiply subordinated (sub) section, increases only logarithmically with the size of the scene or the space 210 or number of sections A, B, C, D, instead of linearly.

As is apparent with reference to the object 710, large objects that are present in multiple sections A, B, C, D of the space 210 are subdivided into subareas or sections (chunks) of the object 710. In the particular section, a bounding box may then be assigned to the respective subareas. The bounding boxes are connected to one another for generating the ray tracing sensor signal. In addition, multiple objects within a section may be combined using a shared bounding box, as shown for the objects 700, 704, the objects 702, 706, and the objects 708, 710 (in part).

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A computer-implemented method for generating a virtual ray tracing sensor signal of a vehicle sensor that is to be virtually tested for testing a virtually simulated or autonomous driving function of an ego vehicle, the method comprising:
providing scene information in a first data format, the scene information comprising information concerning the ego vehicle and at least one object in space;
providing the scene information in a second data format that is converted based on the first data format;
providing the scene information in a third data format that is converted based on the second data format and used for virtual ray tracing of at least one object in space;
subdividing, in the third data format, the space according to a search grid and determining which of the at least one objects interacts with an approximated ray of the vehicle sensor to be virtually tested;
virtual ray tracing, in the third data format, the determined at least one object; and
generating the virtual ray tracing sensor signal based on the traced at least one object for testing the virtually simulated or autonomous driving function of the ego vehicle.

2. The computer-implemented method according to claim 1, further comprising:
transforming coordinates of the determined at least one object from a world coordinate system into a coordinate system of the vehicle sensor to be virtually tested, based on location information of the determined at least one object and/or of the vehicle sensor, which is obtained from the second data format, and based on ray information of the approximated ray; or
transforming coordinates of the vehicle sensor from the world coordinate system into a coordinate system of the determined at least one object based on location information of the determined at least one object and/or of the vehicle sensor, which is obtained from the second data format, and based on ray information of the approximated ray.

3. The computer-implemented method according to claim 2, wherein the location information of the determined at least one object and/or of the vehicle sensor, which is obtained from the second data format, contains information concerning coefficients of a transformation matrix.

4. The computer-implemented method according to claim 1, wherein the scene information also includes movement information of the ego vehicle and/or location and/or movement information concerning the at least one object.

5. The computer-implemented method according to claim 1, wherein the virtual ray tracing sensor signal includes information concerning a distance and/or a speed of the at least one object relative to the ego vehicle.

6. The computer-implemented method according to claim 1, wherein the first data format includes abstract modeling of the at least one object in space, a reference, and/or a pointer to a detailed description of the at least one object in the second data format, and wherein the first data format has a ModelDesk data format.

7. The computer-implemented method according to claim 6, wherein the first data format also includes data and/or information from a driving dynamics simulation of the ego vehicle.

8. The computer-implemented method according to claim 6, wherein the second data format includes a detailed description of the at least one object as information concerning a condition and/or a surface and/or a surface property and/or an object class and/or an object type, and wherein the second data format has an Unreal Engine data format.

9. The computer-implemented method according to claim 1, wherein the third data format includes information concerning vertices into which a surface of the at least one object is subdivided, the information concerning the vertices being used to generate the virtual ray tracing sensor signal as a function of the at least one approximated ray, and wherein the third data format has an Nvidia Optix data format.

10. The computer-implemented method according to claim 4, wherein the movement information of the ego vehicle contains information concerning a predetermined movement by iterative adjustment to the generated ray tracing sensor signal, or by a driving algorithm for movement information that is intended for an autonomous driving function.

11. The computer-implemented method according to claim 1, wherein the method is used in a software-in-a-loop and/or a hardware-in-a-loop test scenario for testing of the vehicle sensor to be virtually tested.

12. The computer-implemented method according to claim 1, wherein the vehicle sensor includes a lidar sensor or a radar sensor or an ultrasound sensor or an infrared sensor.

13. A system for generating a virtual ray tracing sensor signal of a vehicle sensor that is to be virtually tested for testing a virtually simulated or autonomous driving function of an ego vehicle, the system comprising an evaluation and computing device that is designed to carry out the following steps:
providing scene information in a first data format, the scene information containing information concerning the ego vehicle and at least one object in space;
providing the scene information in a second data format that is converted based on the first data format;
providing the scene information in a third data format that is converted based on the second data format and used for virtual ray tracing of at least one object in space;
subdividing, in the third data format, the space according to a search grid and determining which of the at least one objects interacts with an approximated ray of the vehicle sensor to be virtually tested;
virtual ray tracing, in the third data format, the determined at least one object; and
generating the virtual ray tracing sensor signal based on the traced at least one object for testing the virtually simulated or autonomous driving function of the ego vehicle.

14. A computer program product that includes a computer program including software for carrying out the method according to claim 1, the computer program being executed on a computer.

15. A computer-readable data medium that includes program code of a computer program in order to carry out at least parts of the method according to claim 1 when the computer program is executed on a computer.

16. A computer-implemented method for generating a virtual ray tracing sensor signal of a vehicle sensor that is to be virtually tested for testing a virtually simulated or autonomous driving function of an ego vehicle, the method comprising:
providing scene information in a first data format, the scene information containing information concerning the ego vehicle and at least one object in space;
providing the scene information in a third data format that is converted based on the first data format and used for virtual ray tracing of at least one object in space;
subdividing, in the third data format, the space according to a search grid and determining which of the at least one objects interacts with an approximated ray of the vehicle sensor to be virtually tested;
virtual ray tracing, in the third data format, the determined at least one object; and
generating the virtual ray tracing sensor signal based on the traced at least one object for testing the virtually simulated or autonomous driving function of the ego vehicle.

17. The computer-implemented method according to claim 1, wherein the first data format is a 64 bit-based data format, wherein the second data format is a 64 bit-based data format, and wherein the third data format is a 32 bit-based data format.
